(19) United States
(12) Patent Application Publication
(10) Pub. No.: US 2018/0061617 A1
(43) Pub. Date: Mar. 1, 2018

(54) METHOD TO DEPOSIT ALUMINUM OXY-FLUORIDE LAYER FOR FAST RECOVERY OF ETCH AMOUNT IN ETCH CHAMBER

(71) Applicant: Applied Materials, Inc., Santa Clara, CA (US)

(72) Inventors: Jianqi WANG, Fremont, CA (US); Yogita PAREEK, San Jose, CA (US); Julia BAUWIN, San Jose, CA (US); Kevin A. PAPKE, Portland, OR (US)

(21) Appl. No.: 15/663,124

(22) Filed: Jul. 28, 2017

Related U.S. Application Data
(60) Provisional application No. 62/378,536, filed on Aug. 23, 2016.

(51) Int. Cl. H01J 37/32; H01L 21/67; C23C 16/56; C23C 16/40

(52) U.S. Cl. CPC H01J 37/32504; H01L 21/67069; H01J 2237/0213; C23C 16/40; H01J 2237/334; C23C 16/56

(57) ABSTRACT

Implementations of the present disclosure provide a chamber component for use in a processing chamber. The chamber component includes a body for use in a plasma processing chamber, a barrier oxide layer formed on at least a portion of an exposed surface of the body, the barrier oxide layer having a density of about 2 gm/cm³ or greater, and an aluminum oxyfluoride layer formed on the barrier oxide layer, the aluminum oxyfluoride layer having a thickness of about 2 nm or greater.

### CROSS-REFERENCE TO RELATED APPLICATIONS

This application claims priority to United States provisional patent application serial number 62/378,536 filed Aug. 23, 2016, which is herein incorporated by reference.

### FIELD

Embodiments of the present disclosure generally relate to an improved chamber component and methods for treating a chamber component.

### BACKGROUND

Plasma reactors in semiconductor industry are often made of aluminum-containing materials. Particularly in a poly silicon, metal or oxide etch chamber, an aluminum fluoride layer may form on the aluminum surfaces when fluorine containing gases such as NF₃ or CF₄ are used as the etching chemistry. It has been observed that formation of the aluminum fluoride on aluminum chamber surfaces may result in etch rate drifts and chamber instability. The aluminum fluoride on the chamber surfaces may also flake off as a result of the plasma process and contaminate the substrate surface to be processed in chamber with particles.

Therefore, there is a need in the art to provide an improved process to treat chamber components so that etch rate drifting issue and the possibility of aluminum fluoride contamination on substrate surface during processing are minimized or avoided.

### SUMMARY

Implementations of the present disclosure provide a chamber component for use in a processing chamber. The chamber component includes a body for use in a plasma processing chamber, a barrier oxide layer formed on at least a portion of an exposed surface of the body, the barrier oxide layer having a density of about 2 gm/cm³ or greater, and an aluminum oxyfluoride layer formed on the barrier oxide layer, the aluminum oxyfluoride layer having a thickness of about 2 nm or greater.

In another implementation, a method for treating a chamber component is provided. The method includes exposing at least a portion of an exposed surface of a chamber component body to oxygen, wherein the exposed surface of the chamber component body comprises aluminum, and exposing the chamber component body to a solution comprising hydrofluoric acid (HF), ammonium fluoride (NH₄F), ethylene glycol, and water at a temperature of about 5° C. to about 50° C. for about 30 minutes or longer to convert at least a portion of the barrier oxide layer into an aluminum oxyfluoride layer.

In yet another implementation, the method includes forming a barrier oxide layer on at least a portion of an exposed surface of a chamber component body, wherein the exposed surface of the chamber component body comprises aluminum, and forming an aluminum oxyfluoride layer on the barrier oxide layer by exposing the chamber component body to a solution comprising about 29% by volume of 49% hydrofluoric acid (HF), about 11% by volume of 40% ammonium fluoride (NH₄F), and 60% by volume of 100% ethylene glycol at a temperature of about 5° C. to about 50° C. for about 30 minutes or longer.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a flow chart of a method for treating a chamber component for use in a substrate processing chamber.

FIGS. 2A-2B show perspective views of a portion of a chamber component during various stages of method according to the flow chart of FIG. 1.

FIG. 2C shows perspective view of a portion of a chamber component according to an implementation of the present disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

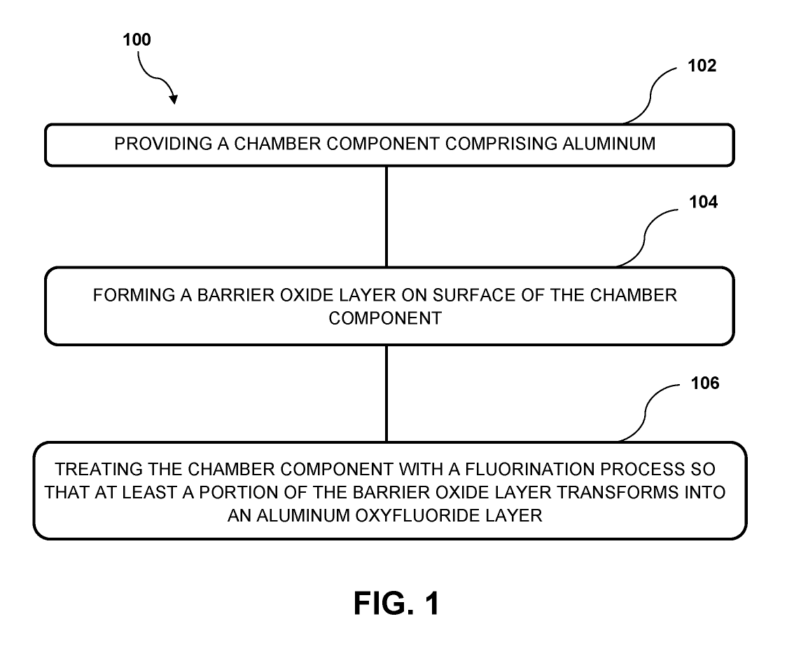

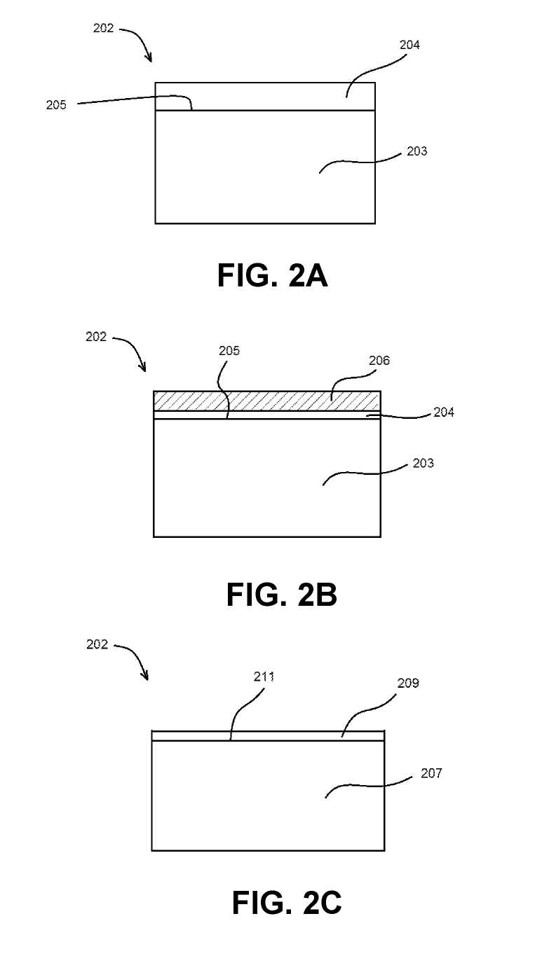

FIG. 1 depicts a flow chart of a method 100 for treating a chamber component for use in a substrate processing chamber, such as a plasma processing chamber. FIG. 1 is illustratively described with reference to FIGS. 2A-2B, which show perspective views of a portion of a chamber component during various stages of method according to the flow chart of FIG. 1. Those skilled in the art will recognize that the structures shown in FIGS. 2A-2B are not drawn to scale. In addition, it is contemplated that although various steps are illustrated in the drawings and described herein, no limitation regarding the order of such steps or the presence or absence of intervening steps is implied. Steps depicted or described as sequential are, unless explicitly specified, merely done so for purposes of explanation without precluding the possibility that the respective steps are actually performed in concurrent or overlapping manner, at least partially if not entirely.

The method 100 starts at block 102 by providing a chamber component 202, as shown in FIG. 2A. The chamber component 202 may be manufactured from aluminum, stainless steel, aluminum oxide, aluminum nitride, or ceramic. The chamber component 202 is shown as a rectangular shape for ease of illustration. It is contemplated that the chamber component 202 may be any part of a plasma processing chamber, such as chamber wall, chamber lid, showerhead, process kit rings, shields, liners, pedestal, or other replaceable chamber component that is exposed to the plasma environment within the processing chamber. The chamber component 202 has a body 203. The body 203 may be fabricated from a single mass of material to form a one-piece body or two or more components welded or otherwise joined together to form a one piece body. In various implementations, the chamber component 202 is a one-piece body 203 formed of aluminum. In some implementations, the chamber component 202 may be a one-piece body formed of stainless steel coated with aluminum, wherein the aluminum coating forms an exposed or exterior surface 205 of the body 203. Alternatively, the chamber component 202 may be any of a core body 207 comprises of an aluminum or a non-aluminum material that is coated with aluminum 209 so that the exposed or exterior surface 211 of the core body 207 is aluminum, as shown in FIG. 2C. While aluminum is discussed, it is contemplated that the exposed or exterior surface 211 can be made of stainless steel, aluminum oxide, aluminum nitride, or ceramic.

At block 104, an optional barrier oxide layer 204 is formed on the exterior surface 205 of the body 203 of the chamber component 202, as shown in FIG. 2A. The barrier oxide layer 204 may be a thin, dense oxide layer. The thin, dense oxide layer may be deposited in a high temperature oxidation furnace using oxygen-containing gas which may include, for example, atomic oxygen (O), molecular oxygen (O₂), ozone (O₃), and/or steam (H₂O), among other oxygen-containing gases. Other oxygen-containing compound, such as tetraethyl orthosilicate (TEOS), may also be used. The barrier oxide layer 204 may have a density of about 2 gm/cm³ or greater, for example about 5 gm/cm³ or greater. The barrier oxide layer 204 may have a thickness of about 2 nm to about 18 nm, such as about 4 nm to about 12 nm, for example about 7 nm to about 10 nm. The thickness of the barrier oxide layer 204 may vary depending upon the processing requirements, or the desired barrier life.

In one exemplary implementation, the barrier oxide layer 204 is formed on the surface of the chamber component 202 in a sub-atmospheric, non-plasma based chemical vapor deposition (CVD) process chamber using ozone and/or TEOS. In such a case, an annealing process may be performed to harden the barrier oxide layer 204. One exemplary annealing process may include heating the chamber component 202 to a temperature of 850° C. or higher (e.g., 1000° C. or higher) for about 10 seconds in an atmosphere of nitrogen gas. The resulting barrier oxide layer 204 may have a density of about 10 gm/cm³ or greater, for example about 15 gm/cm³ or greater.

In some implementations, at least a portion of the barrier oxide layer 204 may be a native oxide that typically forms when the surface of the chamber component 202 is exposed to oxygen. Oxygen exposure occurs when the chamber components are stored at atmospheric conditions, or when a small amount of oxygen remains in a vacuum chamber. Alternatively, the entire barrier oxide layer 204 may be a native oxide.

At block 106, the chamber component 202 is treated with a fluorination process so that at least a portion of the barrier oxide layer 204, or the entire barrier oxide layer 204, transforms into an aluminum oxyfluoride layer 206, as shown in FIG. 2B. The aluminum oxyfluoride layer 206 may have a thickness of about 2 nm to about 18 nm, such as about 4 nm to about 12 nm, for example about 7 nm to about 10 nm. The fluorination process may be performed by exposing (e.g., submerging) the chamber component 202 into a solution containing hydrofluoric acid (HF), ammonium fluoride (NH₄F), ethylene glycol, and water (H₂O) at a temperature range of about 5° C. to about 50° C., for example about 20° C. to about 30° C., for about 30 minutes or longer, such as about 60 minutes or longer, about 120 minutes or longer, about 180 minutes or longer, or about 300 minutes or longer. The hydrofluoric acid and ammonium fluoride react with one another and with the aluminum oxide surface of the chamber component 202 to form the aluminum oxyfluoride layer 206. Specifically, the fluorination process converts a portion or the entire aluminum oxide surface into a protective aluminum oxyfluoride layer 206 on at least a portion of the exposed surface of the chamber component 202. Once the protective aluminum oxyfluoride layer 206 is formed, the underlying aluminum surface is protected from being attacked by the acid in the solution such as hydrofluoric acid. The ethylene glycol also serves to slow down or buffer the etching reaction between the aluminum surface and the hydrofluoric acid, thus protecting the underlying aluminum surface from over-etching by the hydrofluoric acid.

The hydrofluoric acid may be a standard HF solution containing 49% hydrogen fluoride by weight (i.e., 49% HF). The ammonium fluoride may be in solid form or in aqueous solutions. In one implementation, an ammonium fluoride solution of concentration of about 40% NH₄F by weight is used.

In various implementations, the solution may contain about 15%-45% by volume of 49% HF, about 5%-25% by volume of 40% NH₄F, and about 45%-75% by volume of 100% ethylene glycol. In one exemplary implementation (hereinafter embodiment 1), the solution contains about 29% by volume of 49% HF, about 11% by volume of 40% NH₄F, and 60% by volume of 100% ethylene glycol. If a solid form of ammonium fluoride is used, the solution may contain about 20%-40% by volume of 49% HF, about 30 g/L-55 g/L of NH₄F, about 50%-75% by volume of 100% ethylene glycol, and about 2%-12% by volume of water (H₂O). In one exemplary implementation (hereinafter embodiment 2), the solution contains about 31.6% by volume of 49% HF, about 44.6 g/L of NH₄F, 63.1% by volume of 100% ethylene glycol, and 5.4% by volume of water.

Table 1 below illustrates atomic concentrations (in %) of an aluminum oxyfluoride layer (10 nm thickness) treated with the solution used in embodiment 1) under different process times and conditions. The numbers shown in Table 1 are normalized to 100% of the elements detected. No H or He was detected. In addition, a dash line “−” indicates the element is not detected.

TABLE 1

| | Element | | | | | | | | | | | | |
|---|---|---|---|---|---|---|---|---|---|---|---|---|---|
| Run # | C | N | O | F | Mg | Al | Si | S | Cl | Ca | Cu | Zn | F/Al |
| 1 | 20.1 | 0.5 | 41.7 | 17.1 | 0.8 | 19.3 | 0.3 | — | — | — | 0.3 | — | 0.88 |
| 2 | 25.5 | 1.2 | 42.5 | 9.8 | 0.3 | 19.7 | 0.4 | — | — | — | 0.5 | — | 0.50 |
| 3 | 24.7 | 1.6 | 44.4 | 7.4 | 2.2 | 16.5 | 1.9 | — | — | — | 1.1 | 0.2 | 0.45 |
| 4 | 26.1 | 1.9 | 43.9 | 9.3 | 1.0 | 14.8 | 0.6 | 0.6 | 0.5 | 0.7 | 0.3 | 0.4 | 0.63 |
| R | 31.5 | 0.5 | 48.4 | 1.7 | — | 17.0 | 0.5 | 0.3 | 0.2 | — | — | — | 0.10 |
| A1 | 17.7 | 0.3 | 47.8 | 12.2 | <0.1 | 21.1 | 0.4 | — | — | — | 0.4 | — | 0.58 |
| A2 | 26.1 | 0.5 | 33.9 | 14.5 | 0.7 | 20.3 | 0.7 | 0.1 | 0.5 | 0.6 | 1.8 | 0.2 | 0.72 |

Run number 1 to 4 shown in Table 1 represent a chamber component immersed in the solution for 30 minutes, 60 minutes, 90 minutes, and 120 minutes, respectively. Particularly, the fluorination process in run number 1 to 4 was done without having a barrier oxide layer previously formed on the surface of the chamber component. Therefore, the aluminum surface of the chamber component 202 may not have native oxides, or may have only a traceable amount of native oxides. Run number R represents a machined chamber component without any treatment of the inventive fluorination process. Run number A1 and A2 represent a chamber component immersed in the solution for 30 minutes and 60 minutes, respectively. The chamber component in run number A1 and A2 has a barrier oxide layer formed thereon. As can be seen, the chamber component treated with fluorination process (either with or without the barrier oxide layer) show a significant higher concentration of F as compared to Run number R, suggesting the aluminum oxide surface of the chamber component is saturated with fluorine. That is, the aluminum oxyfluoride layer 206 is formed on the surface of the chamber component 202 upon treatment of the chamber component with the fluorination process.

It should be appreciated that the fluorination process using the above-mentioned solution does not substantially etch or erode the aluminum oxide surface of the chamber component 202, thus preserving the aluminum oxide surface of the chamber component 202 and increasing the number of times the chamber component 202 may be cleaned. As used herein “without substantially etch or erode” (or derivations thereof) is intended to mean no detectable attack on the aluminum oxide surface of the chamber component 202 as determined by visual inspection or microscopic measurement to the ten thousandths of an inch (0.0001 inch). In addition, while hydrofluoric acid is discussed, it is contemplated that other chemicals, such as sodium bifluoride, ammonium bifluoride, and ammonium fluoroborate may also be used.

In some implementations, prior to formation of the barrier oxide layer 204 and/or aluminum oxyfluoride layer 206 onto the chamber component 202, the exposed surfaces of the chamber component 202 (or at least the surface to be deposited with the barrier oxide layer 204 and/or aluminum oxyfluoride layer 206) may be roughened to have any desired texture by abrasive blasting, which may include, for example, bead blasting, sand blasting, soda blasting, powder blasting, and other particulate blasting techniques. The blasting may also enhance the adhesion of the barrier oxide layer 204 and/or aluminum oxyfluoride layer 206 to the aluminum surface of the chamber component 202. Other techniques may be used to roughen the exposed surfaces of the chamber component 202 including mechanical techniques (e.g., wheel abrasion), chemical techniques (e.g., acid etch), plasma etch techniques, and laser etch techniques. The exposed surfaces of the chamber component 202 (or at least the surface to be deposited with the barrier oxide layer 204 and/or aluminum oxyfluoride layer 206) may have a mean surface roughness within a range from about 16 microinches (pin) to about 220 pin, such as from about 32 pin to about 120 pin, for example from about 40 pin to about 80 pin.

After the chamber component 202 is treated with the fluorination process, the chamber component can be installed in a processing chamber in which a plasma process is performed.

Benefits of the present disclosure include forming a protective aluminum oxyfluoride layer on aluminum surface or aluminum oxide surface of the chamber components by exposing the chamber component to a solution containing hydrofluoric acid (HF), ammonium fluoride (NH₄F), ethylene glycol, and water (H₂O) at room temperature for at least 30 minutes. Once the protective aluminum oxyfluoride layer is formed, the underlying aluminum oxide surface is protected from being attacked by hydrofluoric acid. The ethylene glycol also buffers the etching reaction between the aluminum oxide surface and the hydrofluoric acid, thus protecting the underlying aluminum surface from over-etching by the hydrofluoric acid. The amount of unstable aluminum fluoride (AIFx) on the aluminum oxide surface is reduced as a result of the formation of the aluminum oxyfluoride layer. In addition, the aluminum oxyfluoride layer reduces the scavenging of F radicals into the aluminum surface of the chamber component and thus improves the etch amount in the processing equipment without having an AlFx contamination. As a result, the etch rate drifting is avoided and chamber stability is improved.

While the foregoing is directed to embodiments of the present disclosure, other and further embodiments of the disclosure may be devised without departing from the basic scope thereof.

What is claimed is:

1. A chamber component for use in a processing chamber, comprising:
a body for use in a plasma processing chamber;
a barrier oxide layer formed on at least a portion of an exposed surface of the body, the barrier oxide layer having a density of about 2 gm/cm³ or greater; and
an aluminum oxyfluoride layer formed on the barrier oxide layer, the aluminum oxyfluoride layer having a thickness of about 2 nm or greater.

2. The chamber component of claim 1, wherein the body comprises aluminum, stainless steel, aluminum oxide, aluminum nitride, or ceramic.

3. The chamber component of claim 1, wherein the body is formed from a single mass of aluminum, stainless steel, aluminum oxide, aluminum nitride, or ceramic.

4. The chamber component of claim 1, wherein the body is formed from a single mass of stainless steel and subsequently coated with aluminum, aluminum oxide, aluminum nitride, or ceramic.

5. The chamber component of claim 1, wherein the body comprises:
a core;
an aluminum coating formed over the core.

6. The chamber component of claim 1, wherein the barrier oxide layer is nature oxide.

7. The chamber component of claim 1, wherein the aluminum oxyfluoride layer has a thickness of about 4 nm to about 12 nm.

8. The chamber component of claim 1, wherein the body has a mean surface roughness of about 16 pin to about 220 pin.

9. A method of treating a chamber component, comprising:
exposing at least a portion of an exposed surface of a chamber component body to oxygen, wherein the exposed surface of the chamber component body comprises aluminum; and
exposing the chamber component body to a solution comprising hydrofluoric acid (HF), ammonium fluoride (NH₄F), ethylene glycol, and water at a temperature of about 5° C. to about 50° C. for about 30 minutes or longer to convert at least a portion of the barrier oxide layer into an aluminum oxyfluoride layer.

10. The method of claim 9, wherein the barrier oxide layer is formed in a high temperature oxidation furnace using an oxygen-containing gas comprising atomic oxygen (O), molecular oxygen (O₂), ozone (O₃), or steam (H₂O).

11. The method of claim 10, wherein the barrier oxide layer has a density of about 2 gm/cm³ or greater.

12. The method of claim 9, wherein the barrier oxide layer is formed by a sub-atmospheric, non-plasma based deposition process using ozone/TEOS.

13. The method of claim 12, wherein the barrier oxide layer is subjected to an annealing process in an atmosphere of nitrogen gas.

14. The method of claim 13, wherein the barrier oxide layer has a density of about 10 gm/cm³ or greater.

15. The method of claim 9, wherein the barrier oxide layer is native oxide.

16. The method of claim 9, wherein the barrier oxide layer has a thickness of about 2 nm to about 18 nm.

17. The method of claim 9, wherein the chamber component body is exposed to the solution at a temperature range of about 20° C. to about 30° C.

18. The method of claim 9, wherein the ammonium fluoride is in solid form or in aqueous solution.

19. A method of treating a chamber component, comprising:
forming a barrier oxide layer on at least a portion of an exposed surface of a chamber component body, wherein the exposed surface of the chamber component body comprises aluminum; and
forming an aluminum oxyfluoride layer on the barrier oxide layer by exposing the chamber component body to a solution comprising about 29% by volume of 49% hydrofluoric acid (HF), about 11% by volume of 40% ammonium fluoride (NH₄F), and 60% by volume of 100% ethylene glycol at a temperature of about 5° C. to about 50° C. for about 30 minutes or longer.

20. The method of claim 19, wherein the barrier oxide layer has a density of about 2 gm/cm³ or greater.
